(19) United States
(12) Patent Application Publication
(10) Pub. No.: US 2012/0282751 A1
(43) Pub. Date: Nov. 8, 2012

(54) METHODS OF FABRICATING SEMICONDUCTOR DEVICES INCLUDING FINE PATTERNS

(75) Inventors: Gyu-hwan OH, Hwaseong-si (KR); Doo-hwan Park, Yongin-si (KR); Dong-hyun Im, Hwaseong-si (KR); Kyung-min Chung, Hwaseong-si (KR)

(73) Assignee: Samsung Electronics Co., Ltd.

(21) Appl. No.: 13/463,342

(22) Filed: May 3, 2012

(30) Foreign Application Priority Data
May 4, 2011 (KR) 10-2011-0042632

(51) Int. Cl. H01L 21/311; H01L 21/02; H01L 21/768; H01L 21/20

(52) U.S. Cl. 438/382; 438/703; 438/478; 438/675; 257/E21.219; 257/E21.09; 257/E21.004; 257/E21.577

(57) ABSTRACT

A method of fabricating an integrated circuit device includes forming first and second patterns extending in first and second directions, respectively, on a target layer. The first patterns comprise a metal oxide and/or metal silicate material having an etch selectivity with respect to that of the target layer. The second patterns comprise a material having an etch selectivity with respect to those of the first patterns and the target layer. The target layer is selectively etched using the first patterns and the second patterns as an etch mask to define holes respectively extending through the target layer to expose a layer therebelow. At least one of the first and second patterns is formed using respective mask patterns formed by a photolithographic process, and the at least one of the first and second patterns have a finer pitch than that of the respective mask patterns.

### CROSS-REFERENCE TO RELATED APPLICATIONS

This application claims the benefit of Korean Patent Application No. 10-2011-0042632, filed on May 4, 2011, in the Korean Intellectual Property Office, the disclosure of which is incorporated herein in its entirety by reference.

### BACKGROUND

The inventive concept relates to semiconductor devices, and more particularly, to methods of fabricating semiconductor devices having contact holes.

As electronic products are manufactured to meet demand for smaller sizes and higher capacity data processing, higher integration of the semiconductor devices used in such electronic products may be needed. However, in semiconductor device fabrication processes, it can be difficult to form fine patterns and/or other features that may be necessary to provide higher integration of the semiconductor devices.

### SUMMARY

The inventive concept provides methods of fabricating a highly-integrated semiconductor device having holes or openings in a target layer.

According to some embodiments of the present inventive concept, a method of fabricating an integrated circuit device includes forming first patterns respectively extending in a first direction on a target layer. The first patterns comprise a metal oxide and/or metal silicate material having an etch selectivity with respect to that of the target layer. Second patterns respectively extending in a second direction different from the first direction are formed on the first patterns. The second patterns comprise a material having an etch selectivity with respect to those of the first patterns and the target layer. The target layer is selectively etched using the first patterns and the second patterns as an etch mask to define holes respectively extending through the target layer to expose a layer therebelow. Forming at least one of the first and second patterns is performed using respective mask patterns formed by a photolithographic process, and the at least one of the first and second patterns have a finer pitch than that of the respective mask patterns.

In some embodiments, the second patterns may be polysilicon, and the holes extending through the target layer may expose portions of active regions and/or conductive lines on a substrate therebelow.

In some embodiments, after selectively etching the target layer, the first and patterns and the metal oxide patterns may be removed from the substrate; and conductive plugs, phase changeable material layers, and/or capacitors may be formed in the holes in the target layer.

In some embodiments, the target layer may be an oxide layer, and selectively etching the target layer using the first patterns and the second patterns as an etch mask may be performed using a fluorocarbon-based etch gas.

In some embodiments, the first patterns may be metal oxide patterns, and the respective mask patterns may be first material layer patterns. The first patterns may be formed by: forming a metal oxide layer on the target layer forming the first material layer patterns extending in the first direction on the metal oxide layer, where the first material layer patterns include a material having an etch selectivity with respect to the metal oxide layer; forming first spacer patterns on opposing sidewalls of the first material layer patterns; forming second material layer patterns extending in the first direction on the metal oxide layer between adjacent first material layer patterns and spaced apart therefrom by the first spacer patterns, the second material layer patterns comprising a material having an etch selectivity with respect to the metal oxide layer; removing the first spacer patterns from between the first and second material layer patterns such that the first and second material layer patterns define first hard mask patterns having a finer pitch than that of the first material layer patterns; and selectively etching the metal oxide layer using the first hard mask patterns as an etch mask to define the metal oxide patterns.

In some embodiments, forming the first material layer patterns may include photolithographically patterning a first material layer on the metal oxide layer using first photoresist patterns having a first pitch as a mask to define the first material layer patterns. The pitch of the first hard mask patterns may be about half of the first pitch or less.

In some embodiments, the second patterns may be cross patterns, and the respective mask patterns may be third material layer patterns. The second patterns may be formed by: forming an overlay layer on the first patterns and on portions of the target layer exposed therebetween, where the overlay layer includes a material having an etch selectivity with respect to the first patterns and the target layer; forming the third material layer patterns extending in the second direction on the overlay layer, where the third material layer patterns include a material having an etch selectivity to the overlay layer; forming second spacer patterns extending in the second direction on opposing sidewalls of the third material layer patterns; removing the third material layer patterns from between the second spacer patterns such that the second spacer patterns define second hard mask patterns on the overlay layer having a finer pitch than that of the third material layer patterns; and selectively etching the overlay layer using the second hard mask patterns as an etch mask to define the cross patterns.

In some embodiments, forming the third material layer patterns may include photolithographically patterning a third material layer using second photoresist patterns having a second pitch as a mask to define the third material layer patterns. The pitch of the third hard mask patterns may be about half of the second pitch or less.

According to some embodiments of the inventive concept, there is provided a method of fabricating a semiconductor device. The method includes: forming a plurality of first hard mask patterns above a substrate on which a target layer and a metal oxide layer are formed so that the plurality of first hard mask patterns extend in a first direction; etching the metal oxide layer using the plurality of first hard mask patterns as etch masks to form metal oxide patterns; forming a buried material layer on the substrate to fill all of spaces which are formed between residues of the first hard mask patterns and the metal oxide patterns; forming a plurality of second hard mask patterns on the buried material layer so that the plurality of second hard mask patterns extend in a second direction different from the first direction; etching the residues of the first hard mask patterns and the buried material layer using the plurality of second hard mask patterns as etch masks to form cross patterns; and etching the target layer through an etching process in which the metal oxide patterns have etch resistance, using the metal oxide patterns and the cross patterns as etch masks to form a plurality of holes.

In some embodiments, the formation of the plurality of first hard mask patterns may include forming first photoresist patterns having a first pitch, wherein each of the plurality of first hard mask patterns is formed to have a second pitch which is about ½ of the first pitch.

In some embodiments, the formation of the plurality of second hard mask patterns may include forming second photoresist patterns having a third pitch, wherein each of the plurality of second hard mask patterns is formed to have a fourth pitch which is about ½ of the third pitch.

In some embodiments, the first and second directions may be substantially perpendicular to each other.

In some embodiments, the formation of the plurality of first hard mask patterns may include: forming a first material layer on the metal oxide layer; forming the first photoresist patterns on the first material layer; etching the first material layer using the first photoresist patterns as etch masks to form first material layer patterns; and forming second material layer patterns in spaces formed between every two adjacent first material layer patterns so that the second material layer patterns are spaced apart from the first material layer patterns, wherein the formation of the plurality of first hard mask patterns further includes: before forming the second material layer patterns, forming first spacer patterns which fill the spaces which are formed between the first and second material layer patterns to be spaced apart from one another; and after forming the second material layer pattern patterns, removing the first spacer patterns.

In some embodiments, the formation of the plurality of second hard mask patterns may include: forming a third material layer on the buried material layer; forming second photoresist patterns on the third material layer; etching the third material layer using the second photoresist patterns as etch masks to form third material layer patterns; forming second spacer patterns in spaces formed between every two adjacent third material layer patterns, wherein the second spacer patterns are spaced apart from one another and cover sidewalls of the first material layer patterns; and removing the third material layer patterns.

In some embodiments, the residues of the first hard mask patterns and the buried material layer may have the same or similar etch characteristics.

In some embodiments, the target layer may be etched using a fluorocarbon gas as an etching gas to form the plurality of holes.

In some embodiments, before forming the metal oxide layer, the method may further include forming a plurality of active areas in the substrate, wherein the plurality of holes are formed so that at least one holes respectively correspond to the plurality of active areas.

In some embodiments, after forming the plurality of holes, the method may further include forming conductive plugs which respectively fill the plurality of holes.

In some embodiments, after forming the plurality of holes, the method may further include forming first and second semiconductor material plugs, wherein the first semiconductor material plugs have first conductive types, and the second semiconductor material plugs have second conductive types different from the first conductive types.

In some embodiments, the first and second semiconductor material plugs may be formed to fully fill the holes, wherein after forming the first and second semiconductor material plugs, the method further includes forming a phase change material layer on the second semiconductor material plugs.

In some embodiments, the first and second semiconductor material plugs may be formed to fill parts of the holes, wherein after forming the first and second semiconductor material plugs, the method further includes forming a phase change material layer on the second semiconductor material plugs so that the phase change material layer fills the holes.

In some embodiments, after forming the plurality of holes, the method may further include forming a phase change material layer which fills the plurality of holes.

According to other embodiments of the inventive concept, there is provided a method of fabricating a semiconductor device. The method includes: forming a plurality of first hard mask patterns above a substrate on which a target layer and a metal oxide layer are sequentially formed so that the first hard mask patterns extend in a first direction and etching the metal oxide layer using the plurality of first hard mask patterns as etch masks to form metal oxide patterns; forming an overlay material layer on the substrate on which the metal oxide patterns are formed; forming a plurality of second hard mask patterns on the overlay material layer so that the plurality of second hard mask patterns extend in a second direction different from the first direction and etching the overlay material layer using the plurality of second hard mask patterns as etch masks to form cross patterns; and etching the target layer through an etching process in which the metal oxide patterns have etch resistance, using the metal oxide patterns and the cross patterns as etch masks to form a plurality of holes, wherein the formation of the plurality of first hard mask patterns includes forming first photoresist patterns having a first pitch, wherein each of the plurality of first hard mask patterns has a second pitch which is about ½ of the first pitch, and the formation of the plurality of second hard mask patterns includes forming second photoresist patterns having a third pitch, wherein each of the plurality of second hard mask patterns has a fourth pitch which is about ½ of the third pitch.

### BRIEF DESCRIPTION OF THE DRAWINGS

Exemplary embodiments of the inventive concept will be more clearly understood from the following detailed description taken in conjunction with the accompanying drawings in which:

FIG. 1 is a cross-sectional view illustrating a process of forming a first material layer according to some embodiments of the inventive concept;

FIG. 2 is a cross-sectional view illustrating a process of forming first photoresist patterns according to some embodiments of the inventive concept;

FIG. 3 is a cross-sectional view illustrating a process of forming first material layer patterns according to some embodiments of the inventive concept;

FIG. 4 is a cross-sectional view illustrating a process of forming first spacer patterns according to some embodiments of the inventive concept;

FIG. 5 is a cross-sectional view illustrating a process of forming second material layer patterns according to some embodiments of the inventive concept;

FIG. 6 is a cross-sectional view illustrating a process of forming first hard mask patterns according to some embodiments of the inventive concept;

FIGS. 7 and 8 are a cross-sectional view and a perspective view illustrating a process of forming metal oxide patterns according to some embodiments of the inventive concept;

FIG. 9 is a perspective view illustrating a process of forming a buried material layer according to some embodiments of the inventive concept;

FIG. 10 is a cross-sectional view illustrating a process of forming second photoresist patterns according to some embodiments of the inventive concept;

FIG. 11 is a cross-sectional view illustrating a process of forming third material layer patterns according to some embodiments of the inventive concept;

FIG. 12 is a cross-sectional view illustrating a process of forming second spacer patterns according to some embodiments of the inventive concept;

FIG. 13 is a cross-sectional view illustrating a process of forming second hard mask patterns according to some embodiments of the inventive concept;

FIG. 14 is a cross-sectional view illustrating a process of forming cross patterns according to some embodiments of the inventive concept;

FIGS. 15 and 16 are a perspective view and a plan view illustrating a process of etching a target layer according to some embodiments of the inventive concept;

FIGS. 17 and 18 are a perspective view and a cross-sectional view illustrating a process of removing metal oxide patterns and cross patterns according to some embodiments of the inventive concept;

FIG. 19 is a cross-sectional view illustrating a process of removing a part of an etch stop layer according to some embodiments of the inventive concept;

FIGS. 20A through 20D are cross-sectional views illustrating a substrate including a target layer in which a plurality of holes are formed, according to some embodiments of the inventive concept;

FIGS. 21A through 21C are cross-sectional views illustrating a phase change memory cell according to some embodiments of the inventive concept;

FIG. 22 is a cross-sectional view illustrating a process of forming conductive plugs according to some embodiments of the inventive concept;

FIGS. 23 through 25C are cross-sectional views illustrating a process of a capacitor according to some embodiments of the inventive concept;

FIGS. 26 through 32 are cross-sectional views illustrating a process of forming holes according to some embodiments of the inventive concept; and

FIGS. 33 through 35 are cross-sectional views illustrating a process of forming holes according to other embodiments of the inventive concept.

### DETAILED DESCRIPTION OF THE EMBODIMENTS

The inventive concept will now be described more fully with reference to the accompanying drawings, in which exemplary embodiments of the inventive concept are shown. The inventive concept may, however, be embodied in many different forms and should not be construed as being limited to the embodiments set forth herein; rather, these embodiments are provided so that this disclosure will be thorough and complete, and will fully convey the inventive concept. In the drawings, the sizes or thicknesses of layers and regions are exaggerated for clarity. Like numbers refer to like elements throughout. As used herein the term “and/or” includes any and all combinations of one or more of the associated listed items and may be abbreviated as “/”.

The terminology used herein is for the purpose of describing particular embodiments only and is not intended to be limiting of the inventive concept. As used herein, the singular forms “a,” “an,” and “the” are intended to include the plural forms as well, unless the context clearly indicates otherwise. It will be further understood that the terms “comprises,” “comprising,” “having,” “having,” “includes,” and/or “including” when used in this specification, specify the presence of stated features, regions, steps, operations, elements, and/or components, but do not preclude the presence or addition of one or more other features, regions, steps, operations, elements, components, and/or groups thereof.

It will be understood that when an element such as a layer or region is referred to as being “on” or extending “onto” another element (or variations thereof), it can be directly on or extend directly onto the other element or intervening elements may also be present. In contrast, when an element is referred to as being “directly on” or extending “directly onto” another element (or variations thereof), there are no intervening elements present. It will also be understood that when an element is referred to as being “connected” or “coupled” to another element (or variations thereof), it can be directly connected or coupled to the other element or intervening elements may be present. In contrast, when an element is referred to as being “directly connected” or “directly coupled” to another element (or variations thereof), there are no intervening elements present.

It will be understood that, although the terms first, second, etc. may be used herein to describe various elements, components, regions, layers and/or sections, these elements, materials, regions, layers and/or sections should not be limited by these terms. These terms are only used to distinguish one element, material, region, layer or section from another element, material, region, layer or section. Thus, a first element, material, region, layer or section discussed below could be termed a second element, material, region, layer or section without departing from the teachings of the present inventive concept.

Relative terms, such as “lower”, “back”, and “upper” may be used herein to describe one element's relationship to another element as illustrated in the Figures. It will be understood that relative terms are intended to encompass different orientations of the device in addition to the orientation depicted in the Figures. For example, if the structure in the FIG. 1 is turned over, elements described as being on the “backside” of substrate would then be oriented on “upper” surface of the substrate. The exemplary term “upper”, can therefore, encompasses both an orientation of “lower” and “upper,” depending on the particular orientation of the figure. Similarly, if the structure in one of the figures is turned over, elements described as “below” or “beneath” other elements would then be oriented “above” the other elements. The exemplary terms “below” or “beneath” can, therefore, encompass both an orientation of above and below.

Embodiments of the present inventive concept are described herein with reference to cross section and perspective illustrations that are schematic illustrations of idealized embodiments of the present inventive concept. As such, variations from the shapes of the illustrations as a result, for example, of manufacturing techniques and/or tolerances, are to be expected. Thus, embodiments of the present inventive concept should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

FIGS. 1 through 8 are cross-sectional views and a perspective view illustrating processes of forming metal oxide patterns according to some embodiments of the inventive concept.

FIG. 1 is a cross-sectional view illustrating a process of forming a first material layer according to some embodiments of the inventive concept.

Referring to FIG. 1, a first material layer 410 is formed on a substrate 100 on which a target layer 200 and a metal oxide layer 300 are formed. An etch stop layer 180 is further provided between the substrate 100 and the target layer 200 in some embodiments.

The substrate 100 may include a semiconductor material, e.g., group IV semiconductor, group III-V compound semiconductor, and/or group II-VI oxide semiconductor. For example, the group IV semiconductor may include silicon, germanium, or silicon-germanium. The substrate 100 may be a bulk wafer or an epitaxial layer. The substrate 100 may also be a silicon-on-insulator (SOI) substrate, a gallium-arsenic substrate, a silicon germanium substrate, a ceramic substrate, a quartz substrate, a display glass, or the like. Unit devices (not shown), such as various types of active or passive elements, used for forming semiconductor devices, may be formed on the substrate 100. Isolation layers (not shown) may be formed to electrically isolate the unit devices from one another. For example, the isolation layers may be formed using a local oxidation of silicon (LOCOS) process or a shallow trench isolation (STI) process. An interlayer insulating layer may be formed on the substrate 100 to cover the unit devices. Conductive areas, which may be electrically connected to the unit devices through the interlayer insulating layer, may be formed in the substrate 100. Conductive lines may be formed to connect the unit devices or the conductive areas to one another. A structure of the substrate 100 will be described in greater detail later.

The target layer 200 may be etched, in a process that will be described later, to form openings or holes therein that expose portions of the underlying substrate 100 including active areas and/or conductive lines thereon. The target layer 200 may be formed of an oxide. The metal oxide layer 300 may be formed of a material having etch selectivity with the target layer 200. The metal oxide layer 300 may be formed of metal oxide and/or metal silicate. For example, the metal oxide layer 300 may be formed of aluminum oxide, hafnium oxide, zirconium oxide, aluminum silicate, hafnium silicate, aluminum-hafnium silicate, zirconium silicate, tungsten oxide, cobalt oxide, ruthenium oxide, iridium oxide, and/or tantalum oxide. The metal oxide layer 300 may have etch selectivity with the target layer 200 in one or more etching processes and/or in a dry etching process using a particular etching gas.

The etch stop layer 180 is used to prevent a part of the substrate 100 from being over-etched due to over-etching of the target layer 200 occurring when the target layer 200 is etched to form holes. The etch stop layer 180 may be formed of nitride. The etch stop layer 180 may be omitted in some embodiments, for example, if the substrate 100 has high etch selectivity with the target layer 200.

The first material layer 410 may be formed of a material having etch selectivity with respect to the target layer 200 and the metal oxide layer 300. For example, the first material layer 410 may be formed of polysilicon. In a process that will be described later, portions of the first material layer 410 and portions of the metal oxide layer 300 may be used as etch masks for etching the target layer 200.

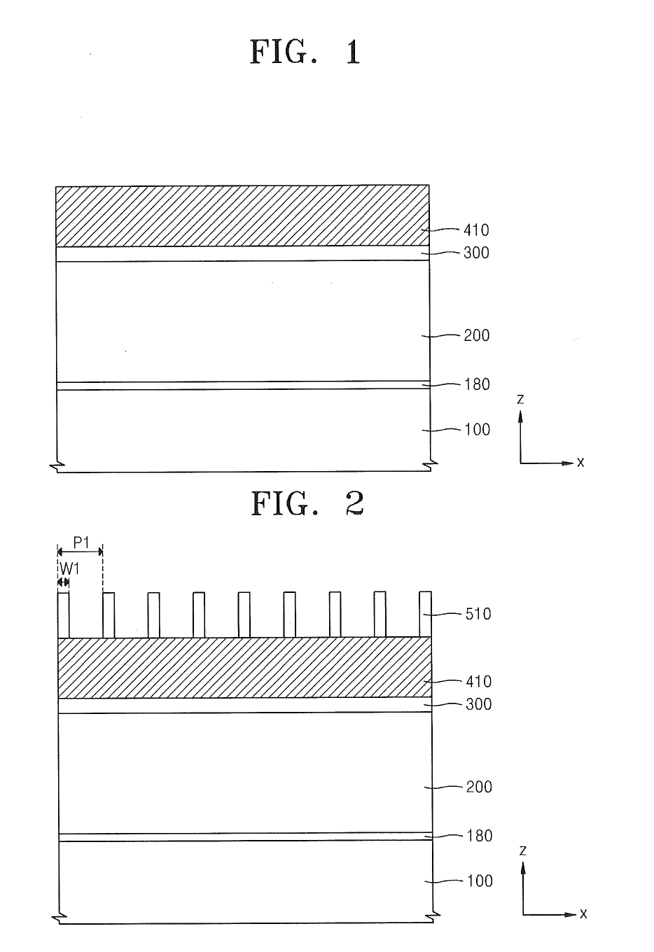

FIG. 2 is a cross-sectional view illustrating a process of forming first photoresist patterns according to some embodiments of the inventive concept.

Referring to FIG. 2, first photoresist patterns 510 are formed on the first material layer 410. The first photoresist patterns 510 may define plurality of lines shapes that extend in one direction (a direction perpendicular to an xz plane in FIG. 2). The first photoresist patterns 510 have first widths W1 and first pitches P1. Each of the first widths W1 may be narrower than about half of each of the first pitches P1 For example, the first width W1 may be ¼ of the first pitch P1 in some embodiments. As used herein, the term “pitch” may refer to the center-to-center distance between adjacent patterns and/or other adjacent features described herein. More generally, “pitch” may refer to a distance between adjacent patterns/features as measured from identical reference points on each pattern/feature. Thus, the pitch may be equal to a sum of (1) the width of the pattern and (2) a distance between immediately adjacent patterns.

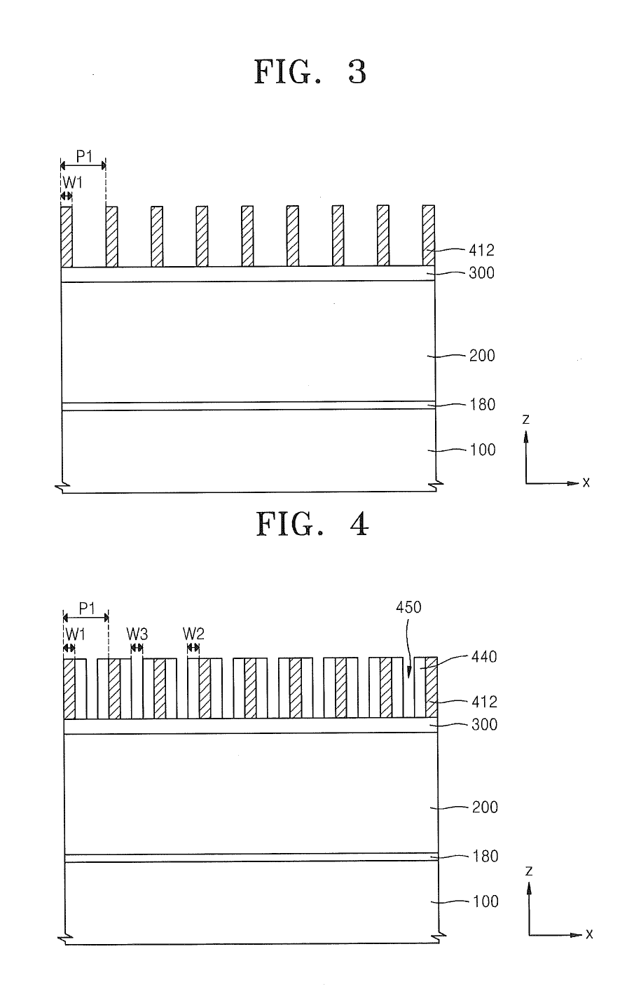

FIG. 3 is a cross-sectional view illustrating a process of forming first material layer patterns according to some embodiments of the inventive concept.

Referring to FIGS. 2 and 3, the first material layer 410 is etched using the first photoresist patterns 510 as etch masks to form first material layer patterns 412. Therefore, the first material layer patterns 412 have first widths W1 and first pitches P1 corresponding to those of the first photoresist patterns 510.

FIG. 4 is a cross-sectional view illustrating a process of forming first spacer patterns according to some embodiments of the inventive concept.

Referring to FIG. 4, first spacer patterns 440 are formed on both opposing sides of each of the first material layer patterns 412. The first spacer patterns 440 have second widths W2. Between adjacent ones of the first spacer patterns 440 (which are respectively formed on sides of adjacent ones of the first material layer patterns 412), first spaces 450 are formed.

The first spaces 450 have third widths W3. The first widths W1 may be the same as the third widths W3. If the first width W1 is ¼ of the first pitch P1, the second width W2 may be ¼ of the first pitch W1, and the third width W3 may be ¼ of the first pitch P1. If the first width W1 is narrower than ¼ of the first pitch P1, the second width W2 may be wider than ¼ of the first pitch P1. If the first width W1 is wider than ¼ of the first pitch P1, the second width W2 may be narrower than ¼ of the first pitch P1 so that the first width W1 may be the same as the third width W3.

To form the first spacer patterns 440, first reserved or initial spacer layers formed to have the second width W2 on the first material layer patterns 412 and exposed surfaces of the metal oxide layer 300. Also, parts of the first reserved spacer layers may be removed through an etch back process to expose upper surfaces of the first material layer patterns 412 and the metal oxide layer 300. The first reserved spacer layers may be formed of oxide. For example, the first reserved spacer layers may be formed of silicon oxide.

FIG. 5 is a cross-sectional view illustrating a process of forming second material layer patterns according to some embodiments of the inventive concept.

Referring to FIGS. 4 and 5, second material layer patterns 414 are formed in the first spaces 450. To form the second material layer patterns 414, a second material layer is formed to fill the first spaces 450, and then a part of the second material layer is removed to expose the first material layer patterns 412 and the first spacer patterns 440. Since the second material layer patterns 414 are formed inside the first spaces 450, the second material layer patterns 414 may have third widths W3.

Therefore, the second material layer patterns 414 formed inside the first spaces 450 formed between adjacent first material layer patterns 412 are spaced apart from adjacent first material layer patterns 412. Also, the first spacer patterns 440 are provided between the first material layer patterns 412 and the second material layer patterns 414,

The second material layer patterns 414 may be formed of a material having etch characteristics the same as or similar to that of the first material layer patterns 412. For example, the second material layer patterns 414 may be formed of polysilicon.

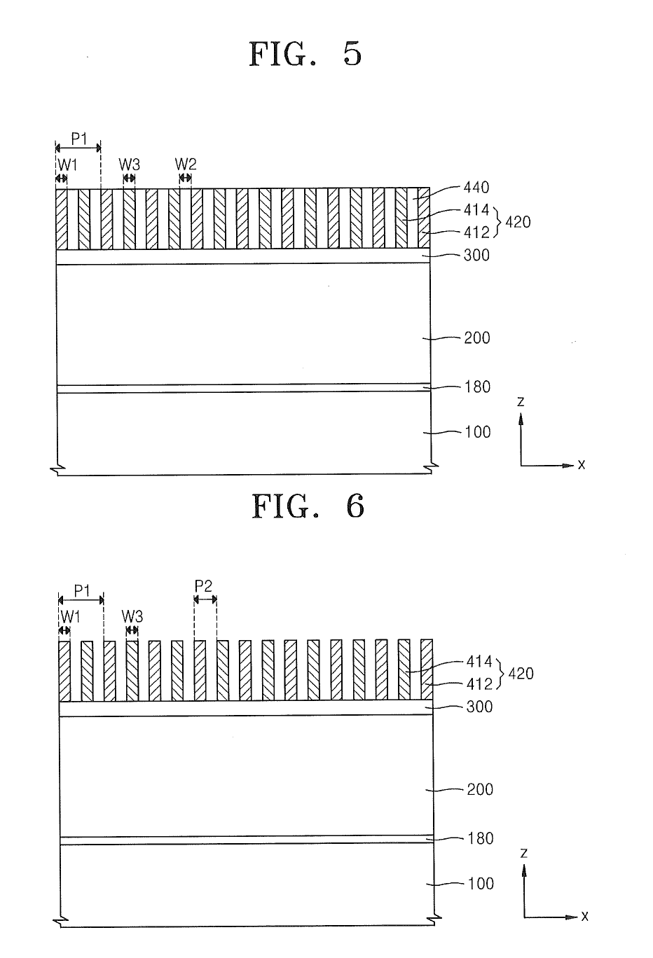

FIG. 6 is a cross-sectional view illustrating a process of forming first hard mask patterns according to some embodiments of the inventive concept.

Referring to FIGS. 5 and 6, the first spacer patterns 440 are removed to form first hard mask patterns 420 including the first material layer patterns 412 and the second material layer patterns 414, The first hard mask patterns 420 include the first and second material layer patterns 412 and 414 and thus have second pitches P2, each of which is about ½ of each of the first pitches P1.

In other words, a photolithography process is used to form the first photoresist patterns 510 illustrated in FIG. 2 and to form the first hard mask patterns 420. Therefore, the first hard mask patterns 420 having the second pitches P2, each of which is about ½ of each of the first pitches P1, are formed through the same photolithography process through which the first pitches P1 may be formed. Thus, two first hard mask patterns 420 may be formed by forming one first photoresist pattern 510. A process of forming a pattern having a second pitch P2, which is finer than (for example, about ½ of) a first pitch P1 of patterns formed through a photolithography process (e.g., to form two patterns within the first pitch P1) is referred to herein as double patterning technology (DPT).

The first hard mask patterns 420 may be formed using various types of DPTs, which may use methods of forming the first material layers 412 separately from the second material layers 414 besides or in addition to the methods described with reference to FIGS. 1 through 6.

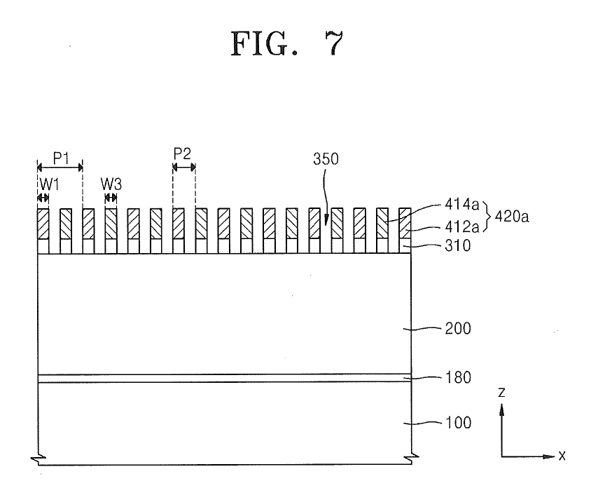

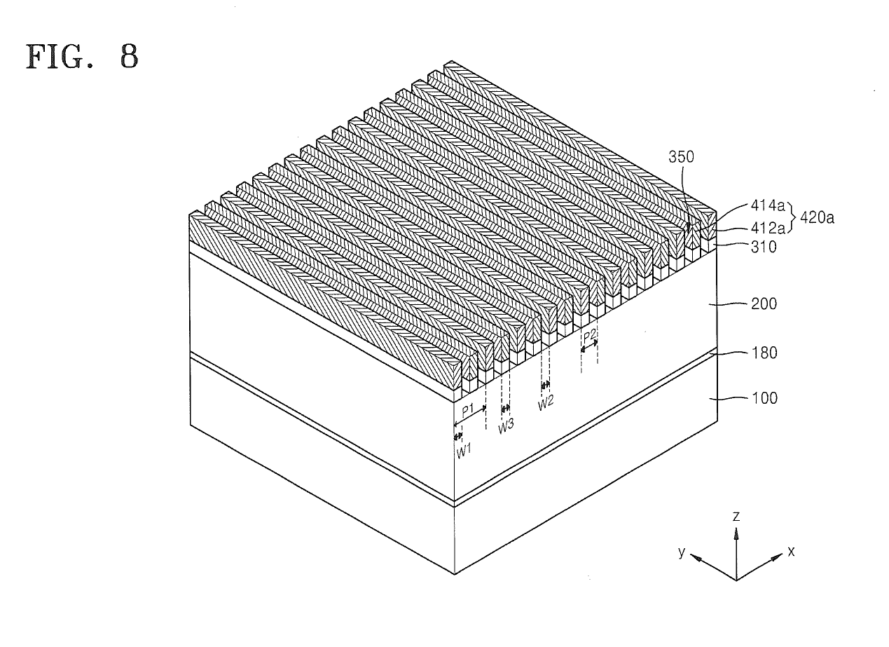

FIGS. 7 and 8 are a cross-sectional view and a perspective view, respectively, illustrating a process of forming metal oxide patterns according to some embodiments of the inventive concept.

Referring to FIGS. 6 through 8, an etching process is performed using the first hard mask patterns 420 as etch masks to remove a part of the metal oxide layer 300 so that the target layer 200 is exposed, thereby forming metal oxide patterns 310 (also referred to herein as first patterns). The metal oxide patterns 310 may be formed through a selective etching process in which the metal oxide layer 300 has different etch selectivity from the target layer 200. For example, the metal oxide patterns 310 may be formed through a dry etching process using boron trichloride (BCl₃).

Alternatively or additionally, a wet etching process may be performed under control of an etching process time to remove a part of the metal oxide layer 300 and expose the target layer 200, thereby forming the metal oxide patterns 310. For example, the metal oxide patterns 310 may be formed through a wet etching process which uses hydrofluoric acid (HF) and/or a buffer oxide etchant (BOE).

The first hard mask patterns 420 may be hardly or partially removed in the etching process for forming the metal oxide patterns 310 and thus may remain as residual first hard mask patterns or first hard mask pattern residues 420a. The hard mask pattern residues 420a include first material layer pattern residues 412a and second material layer pattern residues 414a. An additional process for removing the first hard mask pattern residues 420a may not be performed after the metal oxide patterns 310 are formed. Second spaces 350 are formed between the first hard mask pattern residues 420a and between the metal oxide patterns 310.

As described with reference to FIG. 2, the first photoresist patterns 510 may have respective lines or shapes which extend in one direction (a direction perpendicular to the xz-plane), i.e., a first direction (a y-direction), and are repeatedly arranged along a second direction (an x-direction). Therefore, the first hard mask pattern residues 420a and the metal oxide patterns 310 may have a plurality of line shapes which extend in the first direction (the y direction).

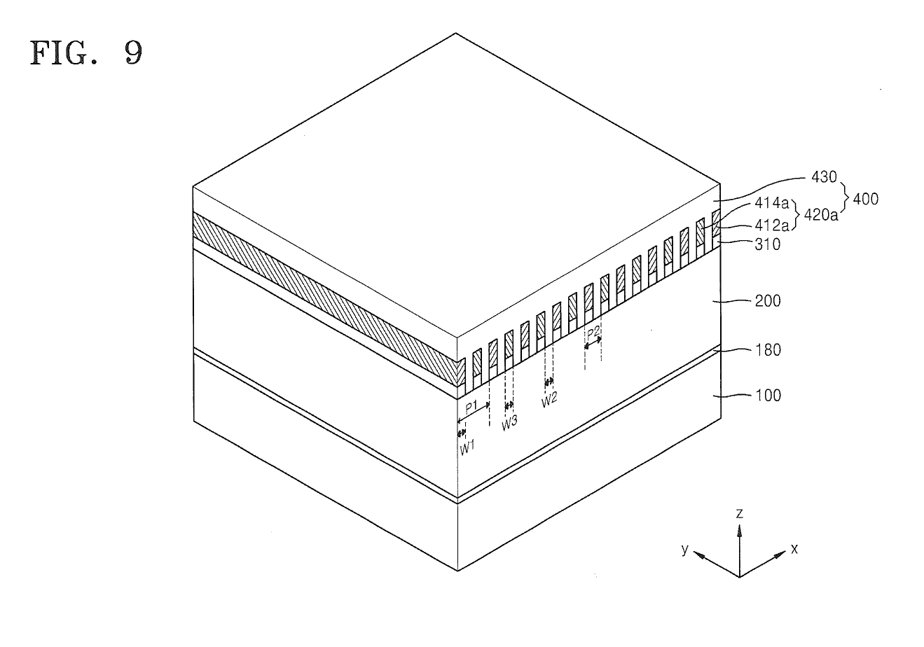

FIG. 9 is a perspective view illustrating a process of forming a buried material layer according to some embodiments of the inventive concept.

Referring to FIGS. 8 and 9, a buried material layer 430 is formed in the second spaces 350. The buried material layer 430 is also formed on the metal oxide patterns 310 and the first hard mask pattern residues 420a. For example, a reserved or initial buried material layer may be formed to cover the metal oxide patterns 310 and the first hard mask pattern residues 420a and may then be planarized, thereby forming the buried material layer 430.

The buried material layer 430 may be formed of a material having etch characteristics the same as or similar to that of the first hard mask pattern residues 420a. For example, the buried material layer 430 may be formed of polysilicon.

If the buried material layer 430 and the first hard mask pattern residues 420a are formed of materials having the same or similar etch characteristics, the buried material layer 430 and the first hard mask pattern residues 420a may be generally referred to as an overlay material layer 400. The overlay material layer 400 has a shape which covers the metal oxide patterns 310. Hereinafter, the overlay material layer 400 will be understood as including the buried material layer 430 and the first hard mask pattern residues 420a.

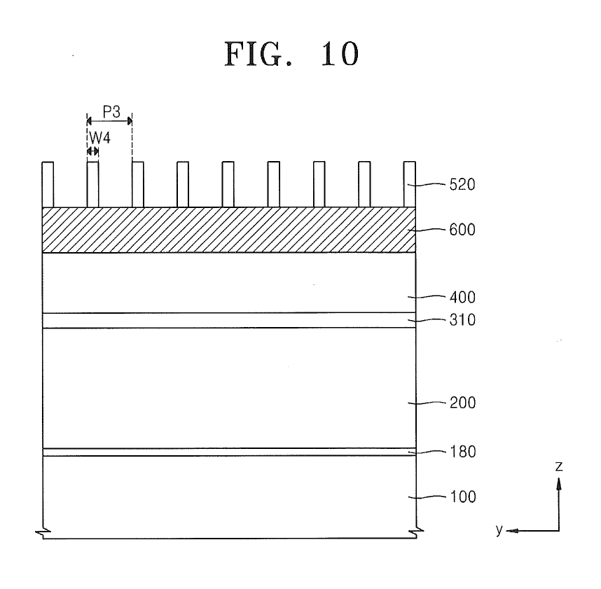

FIG. 10 is a cross-sectional view illustrating a process of forming second photoresist patterns according to some embodiments of the inventive concept.

Referring to FIG. 10, a third material layer 600 is formed on the overlay material layer 400 to cover the overlay material layer 400. The third material layer 600 may be formed of a material having etch selectivity with respect to that of the overlay material layer 400. For example, the third material layer 600 may be formed of a material including carbon. In some embodiments, third material layer 600 may be an amorphous carbon layer (ACL) and/or a spin-on hard mask (SOH). Second photoresist patterns 520 are formed on the third material layer 600. The second photoresist patterns 520 may have respective linear shapes which extend in one direction (a direction perpendicular to a yz plane in FIG. 10). The second photoresist patterns 520 may extend in a different direction from a direction in which the metal oxide patterns 310 extend. For example, the second photoresist patterns 520 may extend in a direction perpendicular to an extension direction of the metal oxide patterns 310. If the first photoresist patterns 510 shown in FIG. 2 extend in a first direction (a y-direction), the second photoresist patterns 520 may extend in a second direction (an x-direction).

The second photoresist patterns 520 have fourth widths W4 and third pitches P3. The fourth width W4 may be narrower than half of the third pitch P3. For example, the fourth width W4 may be about ¼ of the third pitch P3.

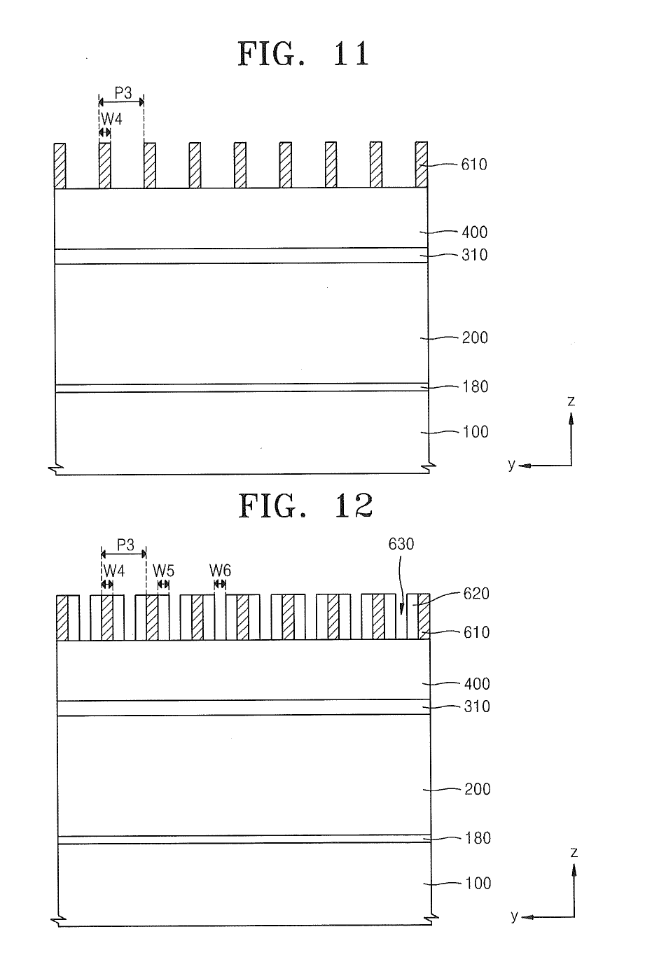

FIG. 11 is a cross-sectional view illustrating a process of forming third material layer patterns according to some embodiments of the inventive concept.

Referring to FIGS. 10 and 11, the third material layer 600 is etched using the second photoresist patterns 520 as etch masks to form third material layer patterns 610. Therefore, the third material layer patterns 610 have the fourth widths W4 and the third pitches P3.

FIG. 12 is a cross-sectional view illustrating a process of forming second spacer patterns according to some embodiments of the inventive concept.

Referring to FIG. 12, second spacer patterns 620 are formed on both opposing sides of each of the third material layer patterns 610. The second spacer patterns 620 have fifth widths W5. Third spaces 630 are formed between two second spacer patterns 620 formed on sides of two third material layer patterns 610, and thus, between any two adjacent third material layer patterns 610. In other words, the two second spacer patterns 620 formed on sides of the two third material layer patterns 610 are spaced apart from each other. The third spaces 630 have sixth widths W6. If the fourth width W4 is ¼ of the third pitch P3, the fifth width W5 may be ¼ of the third pitch P3, and the sixth width W6 may also be ¼ of the third pitch P3.

To form the second spacer patterns 620, second reserved or initial spacer layers (not shown) may be formed to have fifth widths W5 on the third material layer patterns 610 and exposed surfaces of the overlay material layer 400. Also, parts of the second reserved spacer layers may be removed through an etch back process to expose upper surfaces of the third material layer patterns 610 and the overlay material layer 400. The second reserved spacer layers may be formed of oxide. For example, the second reserved spacer layers may be formed of silicon oxide.

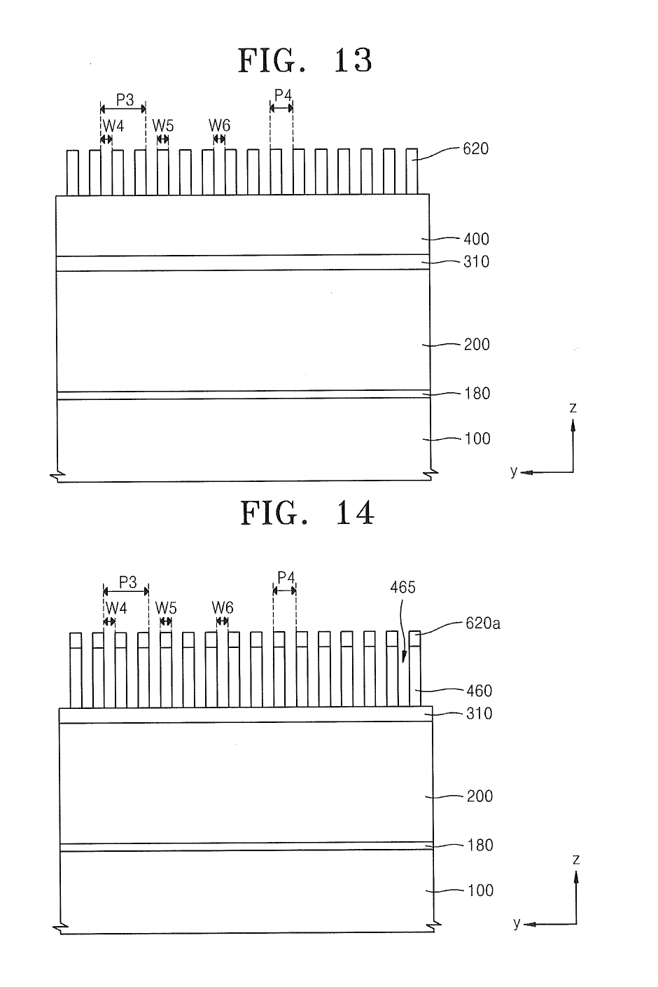

FIG. 13 is a cross-sectional view illustrating a process of forming second hard mask patterns according to some embodiments of the inventive concept.

Referring to FIGS. 12 and 13, the third material layer patterns 610 are removed so that the second spacer patterns 620 remain. The second spacer patterns 620 operate as hard masks in a process that will be described later and thus will be hereinafter referred to as second hard mask patterns 620. The second hard mask patterns 620 may have fourth pitches P4, each of which may be about ½ of each of the third pitches P3.

The second hard mask patterns 620 may be formed using spacers as described with reference to FIGS. 11 through 13 and/or the DPT which may be used to form the first hard mask patterns 420 illustrated in FIGS. 1 through 6.

FIG. 14 is a cross-sectional view illustrating a process of forming cross patterns according to some embodiments of the inventive concept.

Referring to FIGS. 13 and 14, the overlay material layer 400 is selectively etched using the second hard mask patterns 620 as etch masks to form cross patterns 460 (also referred to herein as second patterns). The cross patterns 460 extend in a different direction from a direction in which the metal oxide patterns 310 extend and thus cross over the metal oxide patterns 310. Therefore, the cross patterns 460 and the metal oxide patterns 310 define grid shapes. Since etching is performed to penetrate the overlay material layer 400, thereby forming the cross patterns 460, portions of the target layer 200 on which the metal oxide patterns 310 are not formed may be exposed. Therefore, except for parts of the target layer 200 on which the metal oxide patterns 310 and the cross patterns 460 are formed, parts of the target layer 200 may be exposed.

The cross patterns 460 may be formed through an etching process in which the cross patterns 460 have different etch selectivity with respect to the metal oxide patterns 310 and the target layer 200.

The hard mask patterns 620 may be hardly or partially removed in an etching process for forming the cross patterns 460 and thus may remain as residual hard mask patterns or hard mask pattern residues 620a.

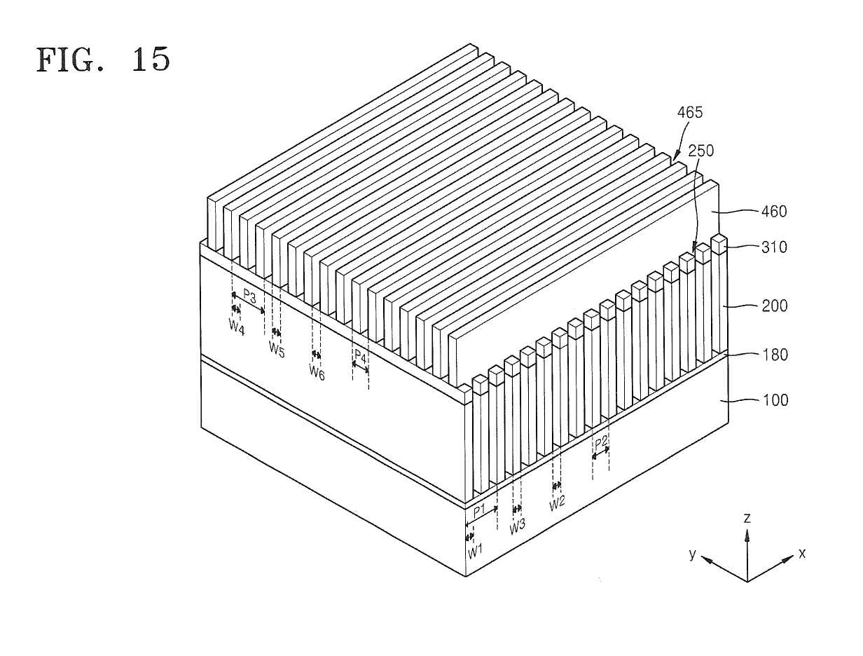

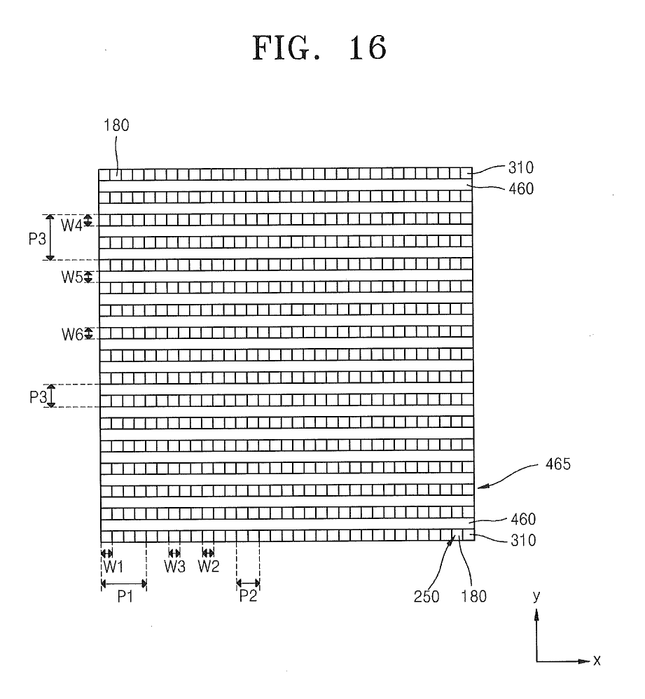

FIGS. 15 and 16 are a perspective view and a plan view illustrating a process of etching the target layer 200 according to some embodiments of the inventive concept.

Referring to FIGS. 15 and 16, the target layer 200 is etched using the metal oxide patterns 310 and the cross patterns 460 as etch masks to form a plurality of holes 250 which penetrate or extend through the target layer 200. The substrate 100 may be exposed through the plurality of holes 250. If the etch stop layer 180 is formed on the substrate 100, the etch stop layer 180 may be exposed through the plurality of holes 250.

The plurality of holes 250 may be formed through an etching process in which the target layer 200 has different etch selectivity with respect to the metal oxide patterns 310 and the cross patterns 460. If the target layer 200 is oxide, etching processes in which the target layer 200 has similar etch selectivity to the metal oxide patterns 310 may be used. Therefore, the target layer 200 may be etched through an etching process in which the metal oxide patterns 310 have etch resistance, thereby forming the plurality of holes 250. For example, the plurality of holes 250 may be formed through a dry etching process using a fluorocarbon (C—F)-based etch gas such as CF₄, C2F₆, C3F₈, CH₂F₂, and/or C₄F₈.

The second hard mask pattern residues 620a shown in FIG. 14 do not need to have different etch selectivity from the target layer 200 and may be removed through an etching process in which the plurality of holes 250 are formed in some embodiments.

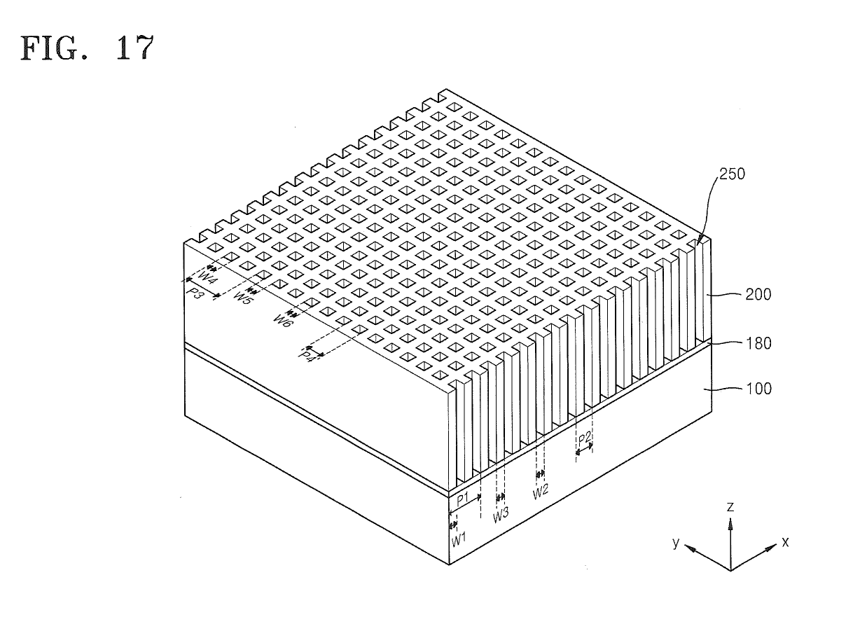

FIGS. 17 and 18 are a perspective view and a cross-sectional view illustrating a process of removing the metal oxide patterns 310 and the cross patterns 460 according to some embodiments of the inventive concept.

Referring to FIGS. 15, 17, and 18, the cross patterns 460 and the metal oxide patterns 310 are removed to expose parts of the target layer 200 formed in the plurality of holes 250. The cross patterns 460 may be removed through an etch back process. The metal oxide patterns 310 may be removed through a wet etching process using HF and/or a BOE.

If the third, fourth, and sixth widths W3, W4, and W6 have the same values, cross-sections of the plurality of holes 250 along a plane that is parallel to the substrate 100 may have square shapes. Alternatively, if the third, fourth, and sixth widths W3, W4, and W6 have different values, the cross-sections of the plurality of holes 250 along a parallel plane with respect to the substrate 100 may have rectangular shapes. If the cross patterns 460 of FIG. 15 cross over the metal oxide patterns 310 of FIG. 15 diagonally and not perpendicularly, the cross-sections of the plurality of holes 250 along a plane that is parallel with respect to the substrate 100 may define parallelogram shapes. The cross-sections of the plurality of holes 250 along a parallel plane with respect to the substrate 100 may also have circular or circle-like shapes according to etching conditions of the etching process for the target layer 200.

Therefore, the holes 250 having widths W3, W4, and/or W6 narrower than those which may be realized using a photolithography process may be formed. For example, if there is a limit to the formation of holes having widths of about 30 nm using a photolithography process, the holes 250 according to some embodiments of the inventive concept may have minimum widths of about 15 nm or less.

FIG. 19 is a cross-sectional view illustrating a process of removing parts of the etch stop layer 180 according to some embodiments of the inventive concept.

Referring to FIG. 19, parts of the etch stop layer 180 exposed in lower parts of the plurality of holes 250 are removed (for example, using the patterned target layer 200 as a mask) to expose the substrate 100. If the etch stop layer 180 is not formed, this process may be omitted.

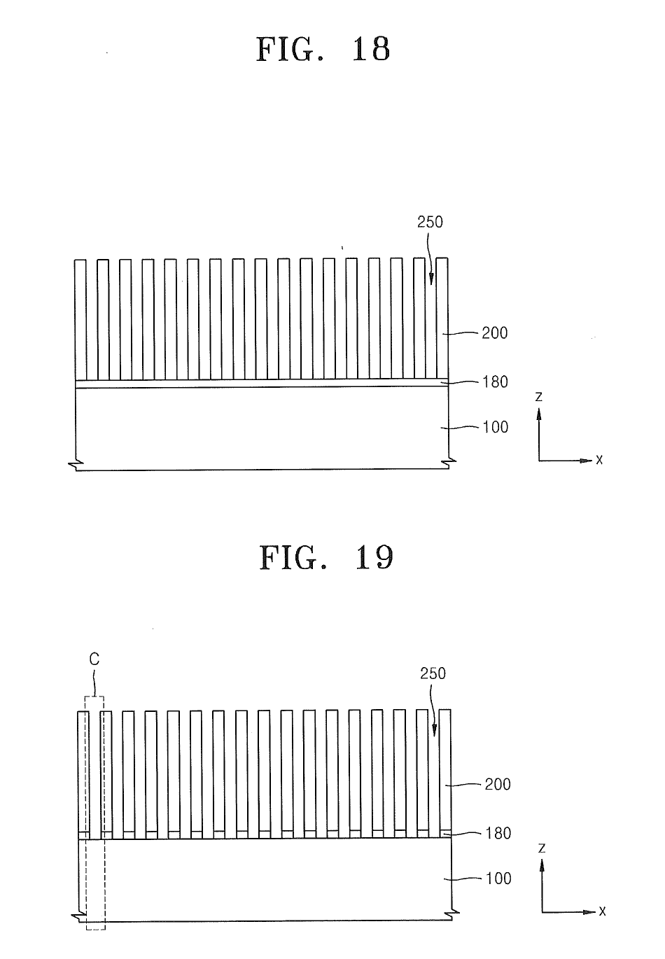

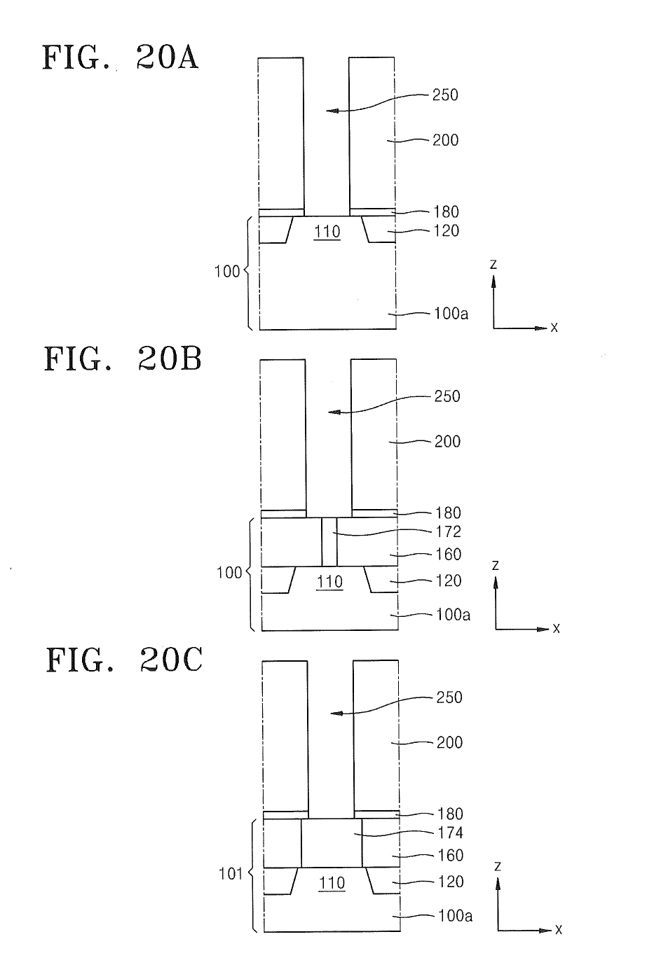

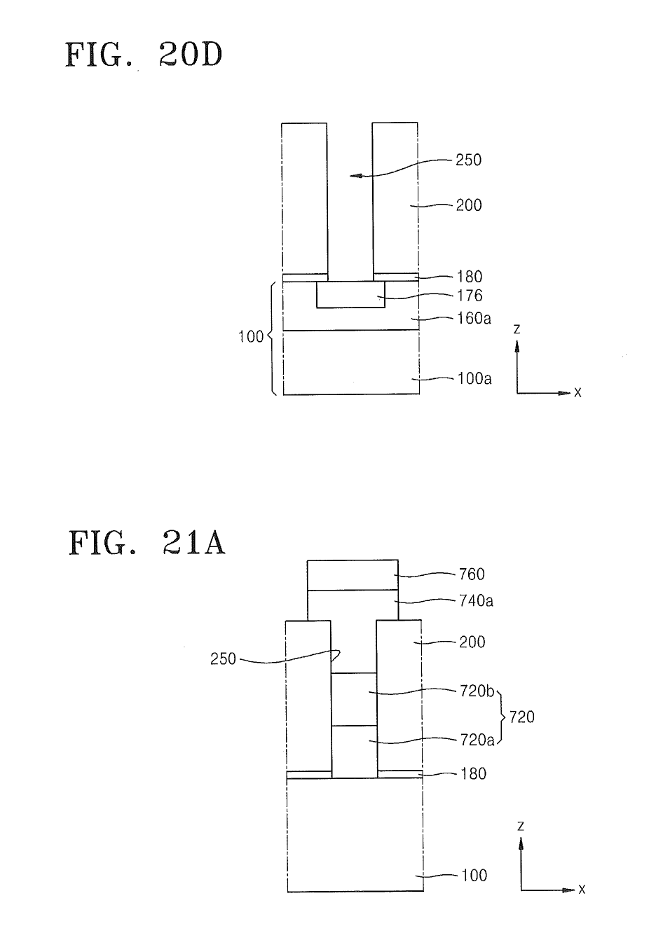

FIGS. 20A through 20D are cross-sectional views illustrating the substrate 100 including the target layer 200 in which the plurality of holes 250 are formed, according to some embodiments of the inventive concept. In more detail, FIGS. 20A through 20D illustrate enlarged cross-sectional views of area C of FIG. 19.

FIG. 20A is a cross-sectional view illustrating the substrate 100 including the target layer 200 in which the hole 250 is formed, according to some embodiments of the inventive concept. Referring to FIG. 20A, the substrate 100 includes an isolation layer 120 which defines a basic material layer 100a and an active area 110. At least one hole 250 is formed in the target layer 200 to correspond to the active area 110 and thus exposes the portion of the substrate 100 including the active area 110 therein. The active area 110 and the isolation layer 120 may be formed before the target layer 200 or the etch stop layer 180 is formed.

The basic material layer 100a may include a semiconductor material, e.g., group IV semiconductor, group III-V compound semiconductor, and/or group II-VI oxide semiconductor. For example, the basic material layer 100a may include group IV semiconductor silicon, germanium, or silicon-germanium. The basic material layer 100a may be an SOI substrate, a gallium-arsenic substrate, a silicon germanium substrate, a ceramic substrate, a quartz substrate, a display glass, or the like.

FIG. 20B is a cross-sectional view illustrating the substrate 100 including the target layer 200 in which the hole 250 is formed, according to another embodiment of the inventive concept. Referring to FIG. 20B, the substrate 100 includes the basic material layer 100a in which the isolation layer 120 defining the active area 110 is formed and an interlayer insulating layer 160 which is formed on the basic material layer 100a. A contact plug 172 is formed in the interlayer insulating layer 160 to penetrate or extend through the interlayer insulating layer 160 to contact the active area 110. Thus, the contact plug 172 is formed to be connected to the active area 110.

The hole 250 in the target layer 200 is formed to face the contact plug 172 and thus exposes an upper surface of the contact plug 172. The contact plug 172 electrically connects the active area 110 to a material that will be formed inside the hole 250.

FIG. 20C is a cross-sectional view illustrating the substrate 100 including the target layer 200 in which the hole 250 is formed, according to another embodiment of the inventive concept. Referring to FIG. 20C, the substrate 100 includes the basic material layer 100a in which the isolation layer 120 defining the active area 110 is formed and the interlayer insulating layer 160 which is formed on the basic material layer 100a. A contact plug 174 is formed in the interlayer insulating layer 160 to penetrate or extend through the interlayer insulating layer 160. The contact plug 174 is connected to the active area 110.

An area of a cross-section of the contact plug 172 of FIG. 20B along a plane parallel to the substrate 100 may be different from an area of a cross-section of the contact plug 174 of FIG. 20C along a plane parallel to the substrate 100. In other words, an entirety of the upper surface of the contact plug 172 of FIG. 20B may be exposed through the hole 250, but less than the entirety of an upper surface of the contact plug 174 of FIG. 20C may be exposed through the hole 250.

FIG. 20D is a cross-sectional view illustrating the substrate 100 including the target layer 200 in which the hole 250 is formed, according to another embodiment of the inventive concept. Referring to FIG. 20D, the substrate 100 includes the basic material layer 100a and an interlayer insulating layer 160a. A conductive line 176 is formed in the interlayer insulating layer 160a. The conductive line 176 is exposed through the hole 250. A material which will be formed inside the hole 250 may be electrically connected to the conductive line 176.

The substrate 100 illustrated in FIGS. 20A through 20D may be selectively applied to some embodiments of the inventive concept.

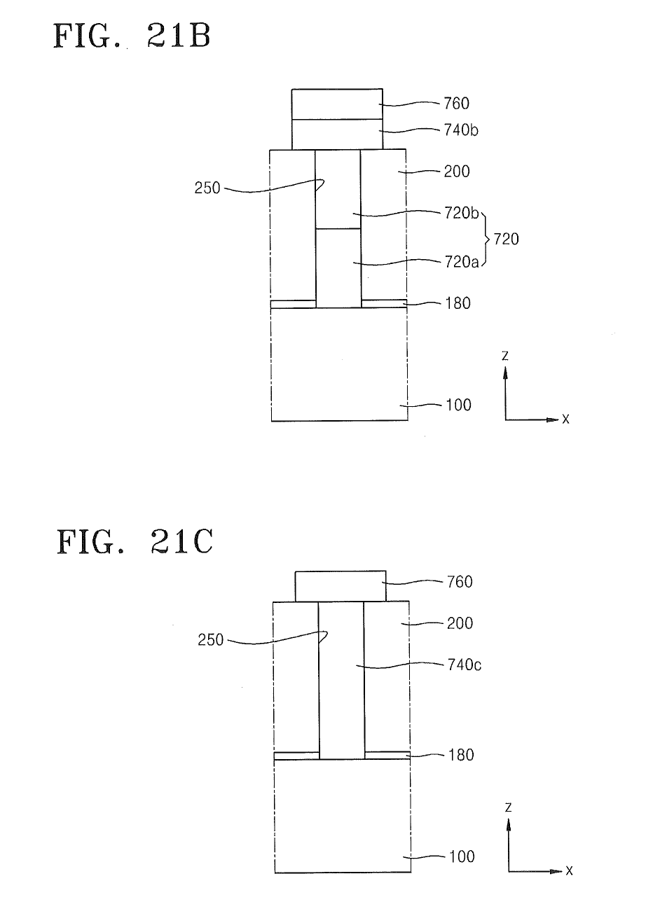

FIGS. 21A through 21C are cross-sectional views illustrating a phase change memory cell according to some embodiments of the inventive concept. In more detail, FIGS. 21A through 21C are enlarged cross-sectional views illustrating the area C of FIG. 19.

FIG. 21A is a cross-sectional view illustrating a phase change memory cell according to some embodiments of the inventive concept. Referring to FIG. 21A, a first semiconductor material plug 720a and a second semiconductor material plug 720b are formed inside the hole 250 formed in the target layer 200. Here, the first semiconductor material plug 720a has a first conductivity type, and the second semiconductor material plug 720b has a second conductivity type different from the first conductivity type. The first and second semiconductor material plugs 720a and 720b are formed to partially fill the hole 250. The first and second semiconductor material plugs 720a and 720b operate as a diode 720 which induces a current to flow in one direction.

A phase changeable or phase change material layer 740a is formed on the diode 720 to further fill the hole 250. The phase change material layer 740a may be formed inside the hole 250 or may be formed both inside the hole 250 and outside the hole 250 on the target layer 200. Therefore, the phase change material layer 740a may be formed on the second semiconductor material plug 720b. An electrode layer 760 is formed on the phase change material layer 740a. To form the phase change material layer 740a and the electrode layer 760, a reserved or initial phase change material layer and a reserved or initial electrode layer may be formed and then may be patterned or otherwise partially removed so that each phase change material layer 740a is isolated from each hole 250. Therefore, the phase change material layer 740a between the diode 720 and the electrode layer 760 may operate as a phase change memory cell.

FIG. 21B is a cross-sectional view illustrating a phase change memory cell according to another embodiment of the inventive concept. Referring to FIG. 21B, the first and second semiconductor material plugs 720a and 720b are formed inside the hole 250 formed in the target layer 200. Here, the first semiconductor material plug 720a has the first conductivity type, and the second semiconductor material plug 720b has the second conductive type different from the first conductive type. The first and second semiconductor material plugs 720a and 720b are formed to fill the hole 250. The first and second semiconductor material plugs 720a and 720b operate as the diode 720 which induces a current to flow in one direction.

A phase changeable or phase change material layer 740b is formed on the diode 720 and the target layer 200. The electrode layer 760 is formed on the phase change material layer 740b. An area of the phase change material layer 740b may be wider than an area of the hole 250. Therefore, the phase change material layer 740b between the diode 720 and the electrode layer 760 may operate as a phase change memory cell.

FIG. 21C is a cross-sectional view illustrating a phase change memory cell according to another embodiment of the inventive concept. Referring to FIG. 21C, a phase change material layer 740c is formed inside the hole 250 formed in the target layer 200,

The electrode layer 760 is formed on the phase change material layer 740c, The phase change material layer 740c is formed to completely fill the hole 250. Alternatively, although not shown, the phase change material layer 740c may fill a part of the hole 250, and the other part of the hole 250 may be filled with the electrode layer 760. Therefore, the phase change material layer 740c between the substrate 100 and the electrode layer 760 operates as a phase change memory cell.

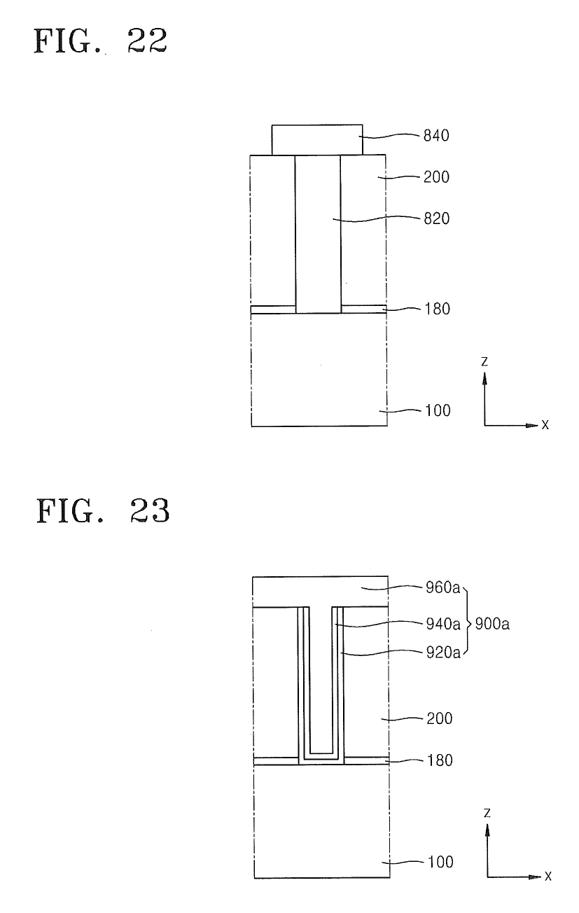

FIG. 22 is a cross-sectional view illustrating a process of forming a conductive plug according to some embodiments of the inventive concept. Referring to FIG. 22, a conductive material is filled inside the hole 250 formed in the target layer 200 to form a conducive plug 820. A conductive wiring line 840 is formed on the conductive plug 820 to be electrically connected to the conductive plug 820.

FIGS. 23 through 25C are cross-sectional views illustrating a process of forming a capacitor according to some embodiments of the inventive concept.

FIG. 23 is a cross-sectional view illustrating a process of forming a capacitor according to some embodiments of the inventive concept. Referring to FIG. 23, a lower electrode layer 920a and a capacitor dielectric layer 940a are formed on a sidewall and a bottom surface of the hole 250 formed in the target layer 200. The lower electrode layer 920a and the capacitor dielectric layer 940a may be formed conformally, so as not to fully fill the hole 250. To form the lower electrode layer 920a and the capacitor dielectric layer 940a, a reserved or initial lower electrode layer and a reserved or initial capacitor dielectric layer can be separately and sequentially formed to cover an inner surface of the hole 250 and an upper surface of the target layer 200. Also, the hole 250 may be filled with a mold material, and then an etch back process or a chemical mechanical polishing (CMP) process may be performed with respect to the mold material. An upper electrode layer 960a is formed to fully fill the hole 250 to form a capacitor 900a.

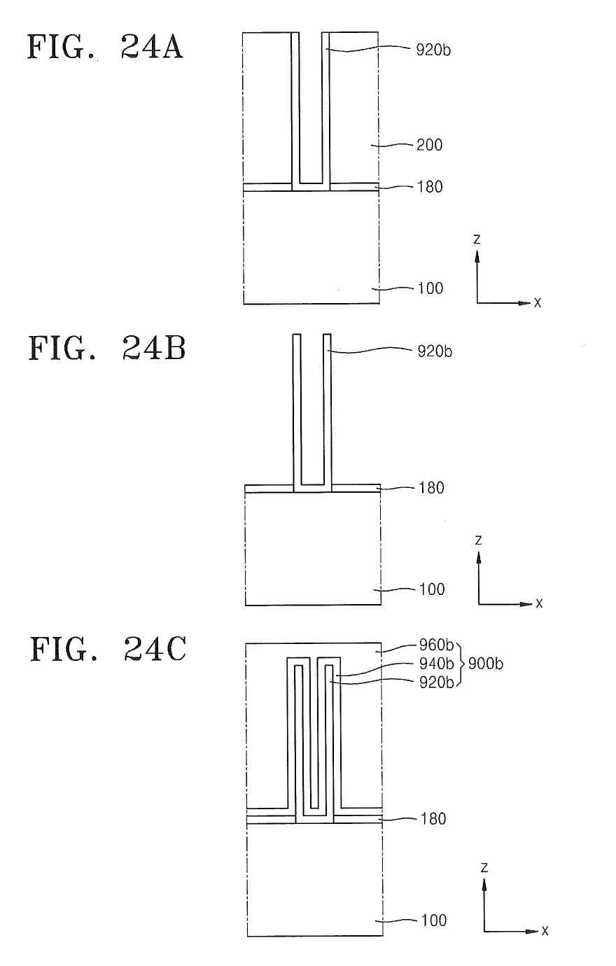

FIGS. 24A through 24C are cross-sectional views illustrating a process of forming a capacitor according to some embodiments of the inventive concept.

Referring to FIG. 24A, a lower electrode layer 920b is formed on the sidewall and bottom of the hole 250 formed in the target layer 200. The lower electrode layer 920b may be formed not to completely or fully fill the hole 250.

Referring to FIG. 24B, the target layer 200 is removed so that the lower electrode layer 920b remains. Therefore, the lower electrode layer 920b may have a pillar shape having an inner space, e.g., a cylinder shape or a rectangular pipe shape.

Referring to FIG. 24C, a capacitor dielectric layer 940b is formed on the substrate 100 to conformally cover an exposed surface of the lower electrode layer 920b, and an upper electrode layer 960b is formed on the capacitor dielectric layer 940b, thereby forming a capacitor 900b.

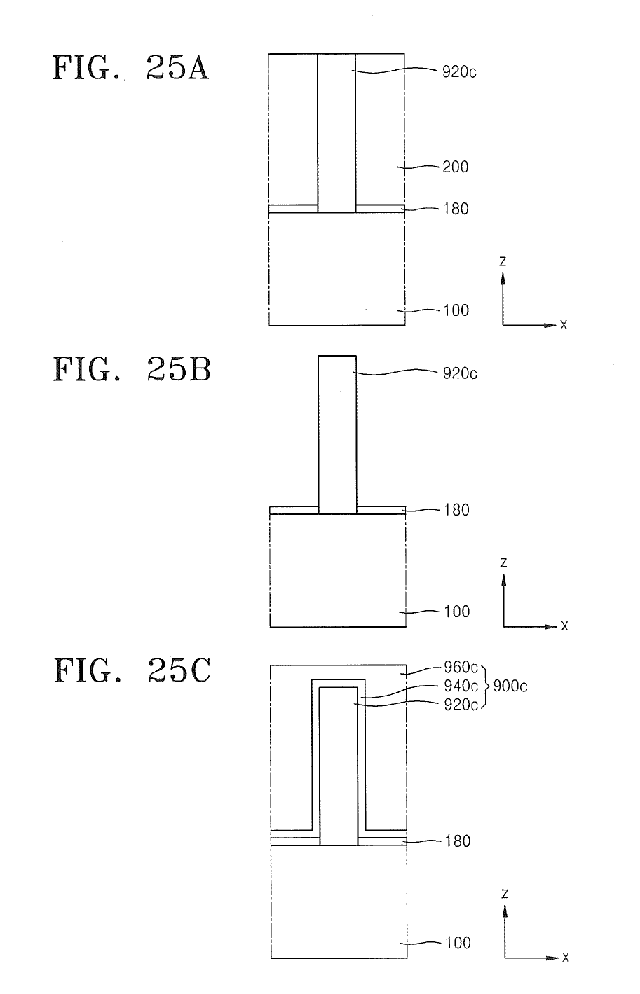

FIGS. 25A through 25C are cross-sectional views illustrating a process of forming a capacitors according to some embodiments of the inventive concept.

Referring to FIG. 25A, a lower electrode layer 920c is formed in the hole 250 formed in the target layer 200. The lower electrode layer 920c may be formed to fully fill the hole 250.

Referring to FIG. 25B, the target layer 200 is removed so that the lower electrode layer 920c remains. Therefore, the lower electrode layer 920c may have a pillar shape.

Referring to FIG. 25C, a capacitor dielectric layer 940c is formed on the substrate 100 to conformally cover an exposed surface of the lower electrode layer 920c, and an upper electrode layer 960c is formed on the capacitor dielectric layer 940c, thereby forming a capacitor 900c.

As illustrated with reference to FIGS. 21A through 25C, capacitors, phase change memory cells, conductive plugs, and/or other components may be formed using the holes 250 formed according to some embodiments of the inventive concept. Also, the substrates 100 illustrated with reference to FIGS. 20A through 20D may be selectively combined to form various types of semiconductor devices and/or semiconductor memory devices.

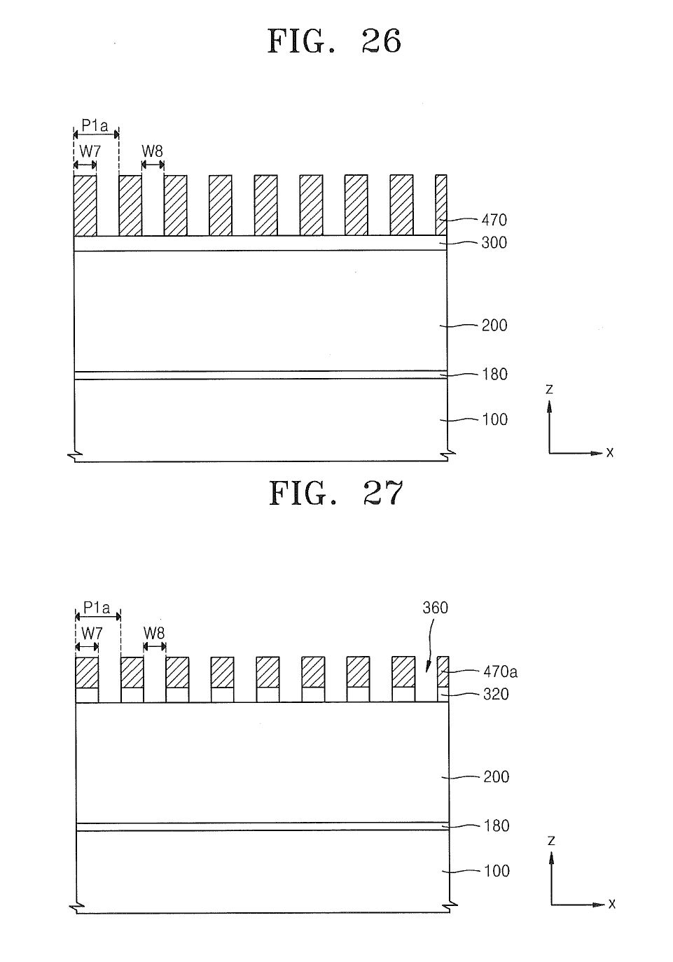

FIGS. 26 through 32 are cross-sectional views illustrating a process of forming holes according to some embodiments of the inventive concept.

FIG. 26 is a cross-sectional view illustrating a process of forming first hard mask patterns according to some embodiments of the inventive concept. In more detail, FIG. 26 illustrates processes performed after the process described with reference to FIG. 1.

Referring to FIG. 26, first hard mask patterns 470 are formed on a substrate 100 on which a target layer 200 and a metal oxide layer 300 are formed. An etch stop layer 180 may be formed on the substrate 100 prior to forming the target layer 200. The first material layer 410 of FIG. 1 may be patterned to form the first hard mask patterns 470. The first hard mask patterns 470 have seventh widths W7 and first pitches P1a. The seventh width W7 may be equal to or wider than about ½ of the first pitch P1a. Spaces having eighth widths W8 are formed between adjacent first hard mask patterns 470.

The first hard mask patterns 420 of FIG. 6 may be formed using DPT so that the two first mask patterns 420 are formed within the first pitch P1. However, the first hard mask patterns 470 of FIG. 26 may be formed so that only one pattern 470 is formed within the first pitch P1a. In other words, the first hard mask patterns 470 may have the same pitch P1a as a photo resist pattern used in formation thereof.

FIG. 27 is a cross-sectional view illustrating a process of forming metal oxide patterns according to some embodiments of the inventive concept.

Referring to FIG. 27, an etching process is performed using the first hard mask patterns 470 as etch masks to remove a part of the metal oxide layer 300 so that the target layer 200 is exposed, thereby forming metal oxide patterns 320.

The first hard mask patterns 470 are hardly or partially removed in the etching process of forming the metal oxide patterns 320 and thus remain as first hard mask pattern residues 470a. After the metal oxide patterns 320 are formed, an additional removal process may not be performed with respect to the first hard mask pattern residues 470a. Second spaces 360 are formed between adjacent metal oxide patterns 320 and the first hard mask pattern residues 470a thereon.

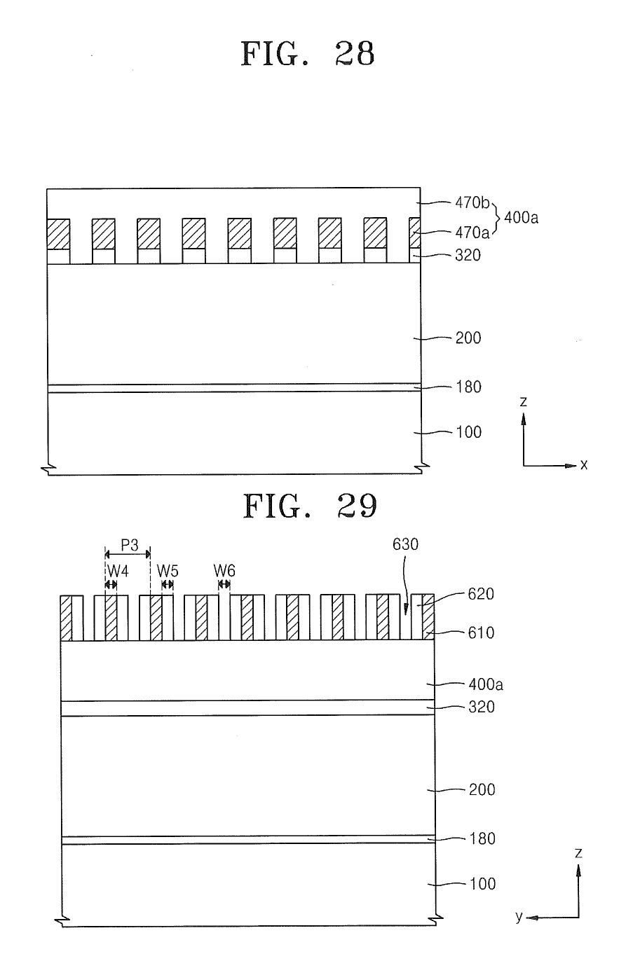

FIG. 28 is a cross-sectional view illustrating a process of forming a buried material layer according to some embodiments of the inventive concept.

Referring to FIGS. 27 and 28, a buried material layer 470b is formed in and/or to fully fill the second spaces 360. The buried material layer 470b is formed to cover all of the metal oxide patterns 320 and the first hard mask pattern residues 470a. A reserved or initial buried material layer may be formed to cover all of the metal oxide patterns 320 and the first hard mask pattern residues 470a and then planarized, thereby forming the buried material layer 470b.

The buried material layer 470b may be formed of a material having etch characteristics the same as or similar to that of the first hard mask pattern residues 470a. If the buried material layer 470b and the first hard mask pattern residues 470a are formed of the materials having the same or similar etch characteristics, the buried material layer 470b and the first hard mask pattern residues 470a may be generally referred to as an overlay material layer 400a. The overlay material layer 400a may have a shape which covers the metal oxide patterns 320. Hereinafter, an element which will be referred to as the overlay material layer 400a will be understood as including the buried material layer 470b and the first hard mask pattern residues 470a.

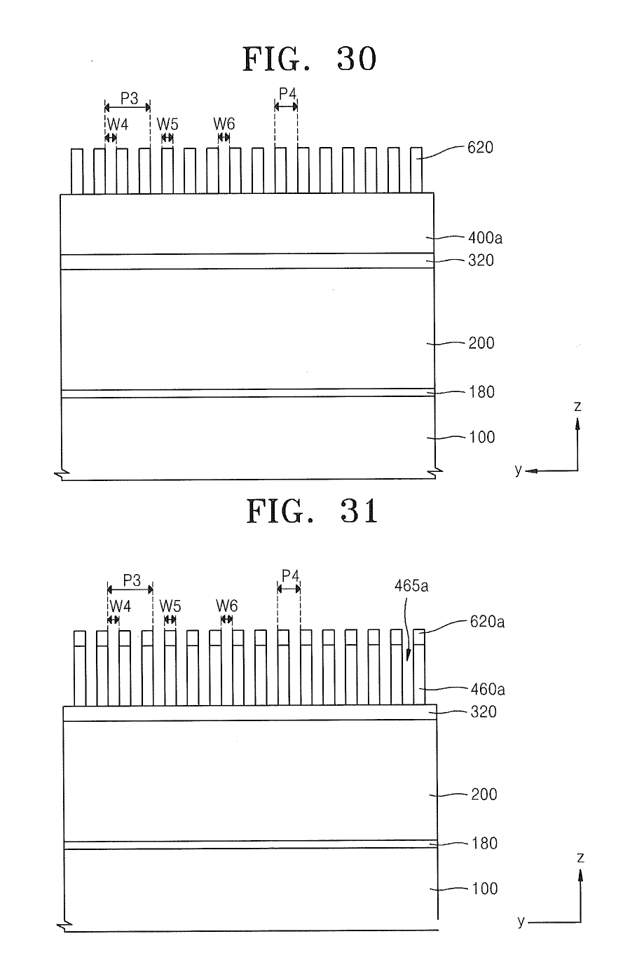

FIGS. 29 and 30 are cross-sectional views illustrating a process of forming second hard mask patterns according to some embodiments of the inventive concept.

Referring to FIGS. 29 and 30, third material layer patterns 610 having fourth widths W4 and third pitches P3 are formed using methods as described with reference to FIGS. 11 through 13. Also, second spacer patterns 620 having fifth widths W5 are formed on both opposing sides of each of the third material layer patterns 610. The third material layer patterns 610 are removed so that the second spacer patterns 620 remain. The second spacer patterns 620 operate as hard masks in a subsequent process and thus will be hereinafter referred to as second hard mask patterns 620. Each of the second hard mask patterns 620 has a fourth pitch P4 which is about ½ of the third pitch P3.

FIG. 31 is a cross-sectional view illustrating a process of forming cross patterns according to some embodiments of the inventive concept.

Referring to FIGS. 30 and 31, the overlay material layer 400a is etched using the second hard mask patterns 620 as etch masks, thereby forming cross patterns 460a. The cross patterns 460a may have shapes which extend in a different direction from an extension direction of the metal oxide patterns 320 and thus cross over the metal oxide patterns 320. Therefore, the cross patterns 460a and the metal oxide patterns 320 may define grid shapes.

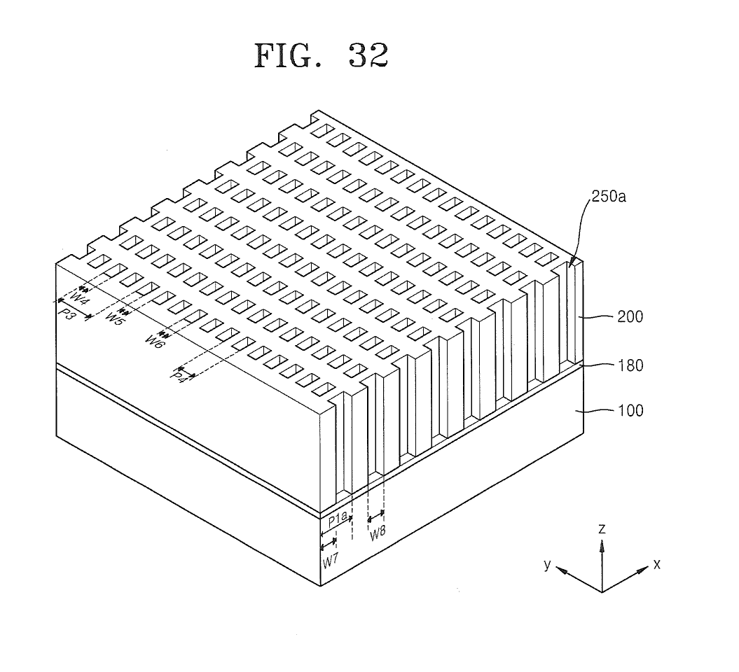

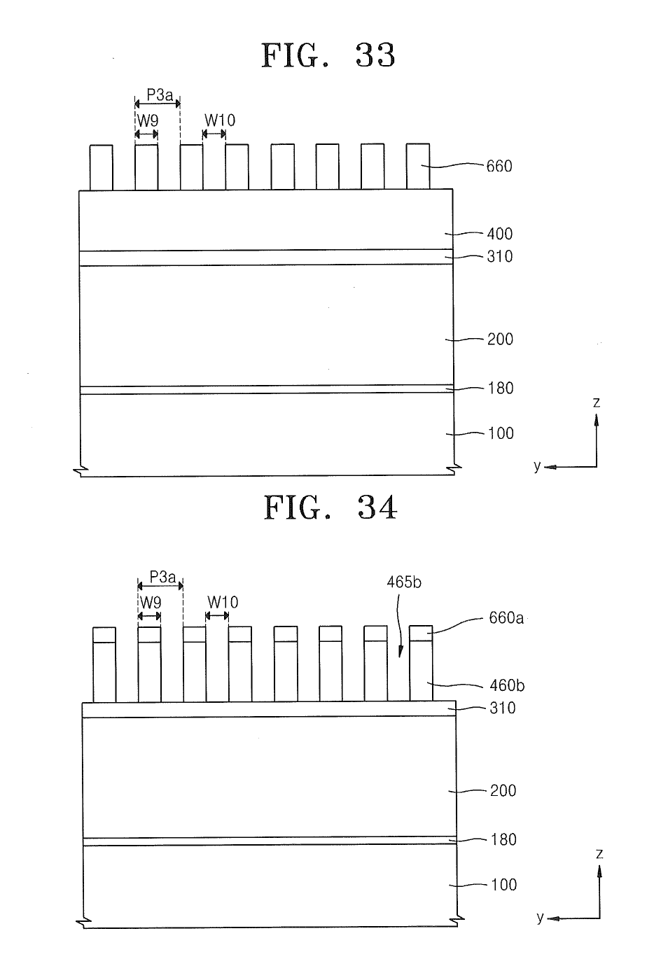

FIG. 32 is a perspective view illustrating a process of forming a plurality of holes according to some embodiments of the inventive concept.

Referring to FIGS. 31 and 32, the target layer 200 is etched using the cross patterns 460a and the metal oxide patterns 320 as etch masks, thereby forming a plurality of holes 250a which penetrate or extend through the target layer 200, The substrate 100 is exposed through the plurality of holes 250a. If the etch stop layer 180 is formed on the substrate 100, the etch stop layer 180 may be exposed through the plurality of holes 250a. The hard mask pattern residues 620a may be removed by the etching process of forming the plurality of holes 250a. The cross patterns 460a and the metal oxide patterns 320 are removed to expose a surface of the target layer 200 in which the plurality of holes 250a are formed, as shown in FIG. 32.

In contrast to the plurality of holes 250 of FIG. 17, the plurality of holes 250a are formed so that widths in a second direction (an x-direction) are different from widths in a first direction (a y-direction). In other words, if photoresist patterns having the same pitches are formed through the two photolithography processes used to form the holes 250 and 250a of FIGS. 17 and 32, the plurality of holes 250 of FIG. 17 may be formed so that widths are the same in the first and second directions (the y- and x-directions). However, the plurality of holes 250a of FIG. 32 may be formed so that widths W8 in the second direction (the x-direction) are greater than (for example, double) the widths W4 and W6 in the first direction (the y-direction). Therefore, cross-sections of the plurality of holes 250a horizontal with respect to the substrate 100 may have bar-shapes, i.e., rectangular shapes.

FIGS. 33 through 35 are cross-sectional views illustrating a process of forming holes according to other embodiments of the inventive concept.

FIG. 33 is a cross-sectional view illustrating a process of forming second hard mask patterns according to some embodiments of the inventive concept. In more detail, FIG. 33 illustrates processes performed after the process described with reference to FIG. 9.

Referring to FIG. 33, second hard mask patterns 660 are formed on the overlay material layer 400. The second hard mask patterns 660 may be formed through a photolithography process after a reserved or initial second hard mask layer is formed. The reserved second hard mask layer may be formed of oxide.

The second hard mask patterns 660 have third pitches P3a and ninth widths W9. Spaces 465b having tenth widths W10 may be formed between adjacent second hard mask patterns 660.

FIG. 34 is a cross-sectional view illustrating a process of forming cross patterns according to some embodiments of the inventive concept.

Referring to FIGS. 33 and 34, the overlay material layer 400 is etched using the second hard mask patterns 660 as etch masks, thereby forming cross patterns 460b having the same pitch P3a as the second hard mask patterns 660. The cross patterns 460b may have shapes which extend in a different direction from an extension direction of metal oxide patterns 310 and thus cross over the metal oxide patterns 310. Therefore, the cross patterns 460b and the metal oxide patterns 310 may define grid shapes.

The second hard mask patterns 660 may be hardly or partially removed in the etching process of forming the cross patterns 460b and thus may remain as second hard mask residues 660a.

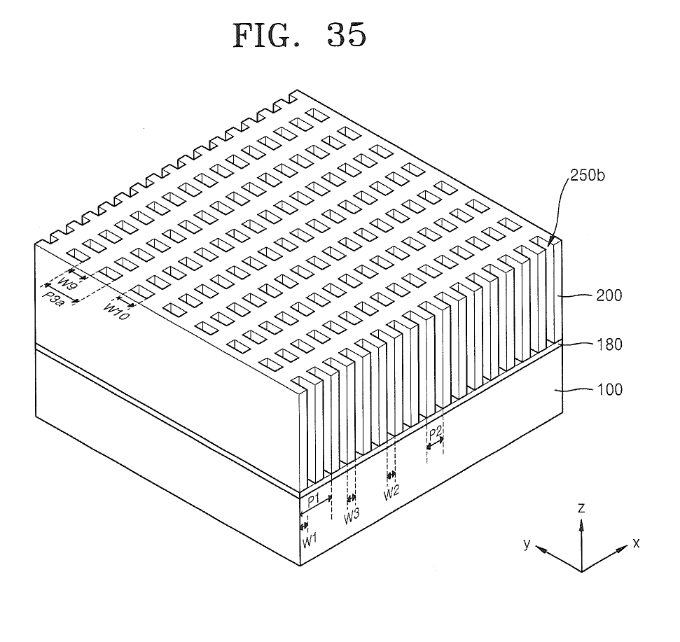

FIG. 35 is a perspective view illustrating a process of forming a plurality of holes according to other embodiments of the inventive concept.

Referring to FIGS. 34 and 35, the target layer 200 is etched using the cross patterns 460b and the metal oxide patterns 310 as etch masks, thereby forming a plurality of holes 250b which penetrate or extend through the target layer 200. The substrate 100 is exposed through the plurality of holes 250b. If the etch stop layer 180 is formed on the substrate 100, the etch stop layer 180 may be exposed through the plurality of holes 250b. The second hard mask pattern residues 620a may be removed by the etching process used in forming the plurality of holes 250b.

The cross patterns 460b and the metal oxide patterns 310 are removed to expose a surface of the target layer 200 in which the plurality of holes 250b are formed.

In contrast to the plurality of holes 250 of FIG. 17, the plurality of holes 250b may be formed so that widths in the first direction (the y-direction) are different from widths in the second direction (the x-direction). In other words, if photoresist patterns having the same pitches are formed through the two photolithography processes used to form the holes 250 and 250b of FIGS. 17 and 35, the plurality of holes 250 of FIG. 17 may be formed so that widths are the same in the first and second directions (the y- and x-directions). However, the plurality of holes 250b of FIG. 35 may be formed so that widths W10 in the first direction (the y-direction) are greater than (for example, double) the widths W2 in the second direction (the x-direction). Therefore, cross-sections of the plurality of holes 250b horizontal with respect to the substrate 100 may have bar shapes, i.e., rectangular shapes.

While the inventive concept has been particularly shown and described with reference to exemplary embodiments thereof, it will be understood that various changes in form and details may be made therein without departing from the spirit and scope of the following claims.

What is claimed is:

1. A method of fabricating an integrated circuit device, the method comprising:
forming first patterns respectively extending in a first direction on a target layer, wherein the first patterns comprise a metal oxide and/or metal silicate material having an etch selectivity with respect to that of the target layer;
forming second patterns respectively extending in a second direction different from the first direction on the first patterns, wherein the second patterns comprise a material having an etch selectivity with respect to those of the first patterns and the target layer; and
selectively etching the target layer using the first patterns and the second patterns as an etch mask to define holes respectively extending through the target layer to expose a layer therebelow,
wherein forming at least one of the first and second patterns is performed using respective mask patterns formed by a photolithographic process, and wherein the at least one of the first and second patterns have a finer pitch than that of the respective mask patterns.

2. The method of claim 1, wherein the second patterns comprise polysilicon, and wherein the holes extending through the target layer expose portions of active regions and/or conductive lines on a substrate therebelow.

3. The method of claim 2, further comprising the following after selectively etching the target layer:
removing the first and patterns and the metal oxide patterns from the substrate; and
forming conductive plugs, phase changeable material layers, and/or capacitors in the holes in the target layer.

4. The method of claim 2, wherein the target layer comprises an oxide layer, and wherein selectively etching the target layer using the first patterns and the second patterns as an etch mask is performed using a fluorocarbon-based etch gas.

5. The method of claim 1, wherein the first patterns comprise metal oxide patterns, wherein the respective mask patterns comprise first material layer patterns, and wherein forming the first patterns comprises:
forming a metal oxide layer on the target layer;
forming the first material layer patterns extending in the first direction on the metal oxide layer, the first material layer patterns comprising a material having an etch selectivity with respect to the metal oxide layer;
forming first spacer patterns on opposing sidewalls of the first material layer patterns;
forming second material layer patterns extending in the first direction on the metal oxide layer between adjacent first material layer patterns and spaced apart therefrom by the first spacer patterns, the second material layer patterns comprising a material having an etch selectivity with respect to the metal oxide layer;
removing the first spacer patterns from between the first and second material layer patterns such that the first and second material layer patterns define first hard mask patterns having a finer pitch than that of the first material layer patterns; and
selectively etching the metal oxide layer using the first hard mask patterns as an etch mask to define the metal oxide patterns.

6. The method of claim 5, wherein forming the first material layer patterns comprises:
photolithographically patterning a first material layer on the metal oxide layer using first photoresist patterns having a first pitch as a mask to define the first material layer patterns,
wherein the pitch of the first hard mask patterns is about half of the first pitch or less.

7. The method of claim 1, wherein the second patterns comprise cross patterns, wherein the respective mask patterns comprise third material layer patterns, and wherein forming the second patterns comprises:
forming an overlay layer on the first patterns and on portions of the target layer exposed therebetween, the overlay layer comprising a material having an etch selectivity with respect to the first patterns and the target layer;
forming the third material layer patterns extending in the second direction on the overlay layer, the third material layer patterns comprising a material having an etch selectivity to the overlay layer;
forming second spacer patterns extending in the second direction on opposing sidewalls of the third material layer patterns;
removing the third material layer patterns from between the second spacer patterns such that the second spacer patterns define second hard mask patterns on the overlay layer having a finer pitch than that of the third material layer patterns; and
selectively etching the overlay layer using the second hard mask patterns as an etch mask to define the cross patterns.

8. The method of claim 7, wherein forming the third material layer patterns comprises:
photolithographically patterning a third material layer using second photoresist patterns having a second pitch as a mask to define the third material layer patterns,
wherein the pitch of the third hard mask patterns is about half of the second pitch or less.

9. A method of fabricating a semiconductor device, comprising:
sequentially forming a target layer and a metal oxide layer on a substrate;
forming a plurality of first hard mask patterns on the target layer so that the plurality of first hard mask patterns extend in a first direction;
etching the metal oxide layer using the plurality of first hard mask patterns as etch masks to define metal oxide patterns including residues of the first hard mask patterns thereon;
forming a buried material layer on the residues of the first hard mask patterns and in spaces between the metal oxide patterns;
forming a plurality of second hard mask patterns on the buried material layer so that the plurality of second hard mask patterns extend in a second direction different from the first direction;
etching buried material layer and the residues of the first hard mask patterns using the plurality of second hard mask patterns as etch masks to define cross patterns; and
etching the target layer through an etching process in which the metal oxide patterns have etch resistance, using the metal oxide patterns and the cross patterns as etch masks to form a plurality of holes extending through the target layer.

10. The method of claim 9, wherein the first and second directions are perpendicular to each other.

11. The method of claim 10, wherein forming the plurality of first hard mask patterns comprises:
forming a first material layer on the metal oxide layer;
forming the first photoresist patterns on the first material layer;
etching the first material layer using the first photoresist patterns as etch masks to form first material layer patterns;
forming first spacer patterns on opposing sidewalls of the first material layer patterns to define spaces therebetween;
forming second material layer patterns in the spaces between adjacent ones of the first spacer patterns so that the second material layer patterns are spaced apart from the first material layer patterns; and
after forming the second material layer pattern patterns, removing the first spacer patterns such that the first and second material layer patterns define the first hard mask patterns.

12. The method of claim 10, wherein forming the plurality of second hard mask patterns comprises:
forming a third material layer on the buried material layer;
forming the second photoresist patterns on the third material layer;
etching the third material layer using the second photoresist patterns as etch masks to form third material layer patterns;
forming second spacer patterns in spaces between adjacent ones of the third material layer patterns, wherein the second spacer patterns are spaced apart from one another and cover sidewalls of the third material layer patterns; and
removing the third material layer patterns such that the second spacer patterns define the second hard mask patterns.

13. The method of claim 9, wherein the residues of the first hard mask patterns and the buried material layer have same or similar etch characteristics.

14. The method of claim 9, before forming the metal oxide layer, further comprising:
forming a plurality of active areas in the substrate,
wherein the plurality of holes are formed so that one or more of the plurality of holes respectively corresponds to one or more of the plurality of active areas.

15. The method of claim 14, after forming the plurality of holes, further comprising:
forming conductive plugs which respectively fill corresponding ones of the plurality of holes.

16. The method of claim 9, after forming the plurality of holes, further comprising:
sequentially forming first and second semiconductor material plugs in the holes, wherein the first semiconductor material plugs have a first conductivity type, and wherein the second semiconductor material plugs have a second conductivity type different from the first conductivity type.

17. The method of claim 16, wherein the first and second semiconductor material plugs are formed to completely fill the holes, and wherein, after forming the first and second semiconductor material plugs, the method further comprises forming respective phase change material layers on the second semiconductor material plugs.

18. The method of claim 16, wherein the first and second semiconductor material plugs are formed to partially fill the holes, and wherein, after forming the first and second semiconductor material plugs, the method further comprises forming respective phase change material layers on the second semiconductor material plugs so that the respective phase change material layers fill the holes.

19. The method of claim 9, further comprising:
after forming the plurality of holes, forming a phase change material layer which fills the plurality of holes.

20. A method of fabricating a semiconductor device, comprising:
forming a plurality of first hard mask patterns on a substrate on which a target layer and a metal oxide layer are sequentially formed so that the first hard mask patterns extend in a first direction on the metal oxide layer;
etching the metal oxide layer using the plurality of first hard mask patterns as etch masks to form metal oxide patterns extending in the first direction;
forming an overlay material layer on the metal oxide patterns;
forming a plurality of second hard mask patterns on the overlay material layer so that the plurality of second hard mask patterns extend in a second direction different from the first direction;
etching the overlay material layer using the plurality of second hard mask patterns as etch masks to form cross patterns extending in the second direction; and
etching the target layer through an etching process in which the metal oxide patterns have etch resistance, using the metal oxide patterns and the cross patterns as etch masks to form a plurality of holes in the target layer,
wherein forming the plurality of first hard mask patterns comprises forming first photoresist patterns having a first pitch, wherein the plurality of first hard mask patterns has a second pitch which is about ½ of the first pitch, and wherein forming the plurality of second hard mask patterns comprises forming second photoresist patterns having a third pitch, wherein the plurality of second hard mask patterns has a fourth pitch which is about ½ of the third pitch.
